(19) United States
(12) Patent Application Publication
(10) Pub. No.: US 2025/0109673 A1
(43) Pub. Date: Apr. 3, 2025

(54) Estimating a Gas Rate using a Generative Adversarial Network

(71) Applicant: Saudi Arabian Oil Company, Dhahran (SA)

(72) Inventors: Abdullah M. Bin Ziad, Udhailiyah (SA); Abdulmajeed M. Alotaibi, Udhailiyah (SA); Fahad O Alshammari, Udhailiyah (SA)

(21) Appl. No.: 18/477,150

(22) Filed: Sep. 28, 2023

(51) Int. Cl. E21B 43/30; E21B 49/00

(52) U.S. Cl. CPC E21B 43/30; E21B 49/003; G06F 30/27; G06N 3/045; G06N 3/08

(57) ABSTRACT

A computer implemented method for estimating a gas rate using a generative adversarial network is described. The method includes inputting training data to a generator. The method includes providing input to a discriminator, the input comprising the generated data samples and real data samples, wherein the discriminator outputs a binary classification of the input. Additionally, the method includes training the discriminator and the generator by evaluating the output of the discriminator, and estimating gas rates using the trained generator.

### TECHNICAL FIELD

This disclosure relates generally to estimating a gas rate.

### BACKGROUND

Flowback refers to process fluids from the wellbore that return to the surface and are collected after wells are completed, such as after hydraulic fracturing. In addition to the hydraulic fracturing fluids originally pumped, returned fluids contain volatile hydrocarbons from the formation. After separation, flowback fluids are typically stored temporarily in tanks or surface impoundments at the well site.

### SUMMARY

An embodiment described herein provides a method for predicting gas rate using a Generative Adversarial Network. The method includes inputting, using at least one hardware processor, training data into a generator, wherein the generator outputs generated data samples. The method includes providing, using the at least one hardware processor, input to a discriminator, the input comprising the generated data samples and real data samples, wherein the discriminator outputs a binary classification of the input. The method includes training, using the at least one hardware processor, the discriminator and the generator by evaluating the output of the discriminator, wherein parameters of the discriminator and generator are iteratively updated based on the output of the discriminator. The method includes estimating, using the at least one hardware processor, gas rates using the trained generator.

An embodiment described herein provides an apparatus comprising a non-transitory, computer readable, storage medium that stores instructions that, when executed by at least one processor, cause the at least one processor to perform operations. The operations include inputting training data to a generator, wherein the generator outputs generated data samples. The operations include providing input to a discriminator, the input comprising the generated data samples and real data samples, wherein the discriminator outputs a binary classification of the input. The operations include training the discriminator and the generator by evaluating the output of the discriminator, wherein parameters of the discriminator and generator are iteratively updated based on the output of the discriminator. The operations include estimating gas rates using the trained generator.

An embodiment described herein provides a system. The system comprises one or more memory modules and one or more hardware processors communicably coupled to the one or more memory modules. The one or more hardware processors is configured to execute instructions stored on the one or more memory models to perform operations. The operations include inputting training data to a generator, wherein the generator outputs generated data samples. The operations include providing input to a discriminator, the input comprising the generated data samples and real data samples, wherein the discriminator outputs a binary classification of the input. The operations include training the discriminator and the generator by evaluating the output of the discriminator, wherein parameters of the discriminator and generator are iteratively updated based on the output of the discriminator. The operations include estimating gas rates using the trained generator.

In any of the preceding embodiments, the binary classification classifies the inputs of the discriminator as real data or fake data.

In any of the preceding embodiments, the training data is historical data obtained from previously drilled wells.

In any of the preceding embodiments, the real data is historical data obtained from previously drilled wells.

In any of the preceding embodiments, evaluating the discriminator comprises calculating at least one performance metric and determining that the at least one performance metric satisfies a corresponding performance metric threshold.

In any of the preceding embodiments, the generator is trained using regression analysis.

In any of the preceding embodiments, the estimated gas rates are used to determine locations for new wells.

### BRIEF DESCRIPTION OF DRAWINGS

FIG. 1 is shows a generative adversarial network (GAN) that predicts gas rates according to the present techniques.

FIG. 2 is a plot of the learning curves associated with a GAN.

FIG. 3 is a GAN scatter plot.

FIG. 4 is a process flow diagram of a method for predicting gas rates using a GAN.

FIG. 5 illustrates hydrocarbon production operations that include both one or more field operations and one or more computational operations.

FIG. 6 is a schematic illustration of an example controller for estimating gas rate using a generative adversarial network.

### DETAILED DESCRIPTION

Flowback includes fluids that flow from a well following completion of the well or treatment at the well. In examples, flowback operations represent a volatile production period occurring either in preparation for various phases of treatment, cleanup, or in preparation of production. For example, a well is drilled and completed, and production equipment used to flow the well is installed, including tanks, separators, and interconnecting piping. Flowback occurs when the well is opened, and initial fluids are produced from the well. The initial fluids can include, for example, crude oil, gas, water, and sand.

Flowback of a well is a determinant of economic viability of the well. Flowback parameters, such as hydrocarbon flow rates, are used to determine various aspects of the well in post-drilling evaluations and ongoing production and reservoir engineering applications. Hydrocarbon flow rates, such as a gas flow rate, can be costly to determine and have varying accuracies. The present techniques enable the estimation of a gas rate using a deep learning generative adversarial network. Estimating gas rates using a generative adversarial network (GAN) provides an accurate gas rate estimation at a minimal cost.

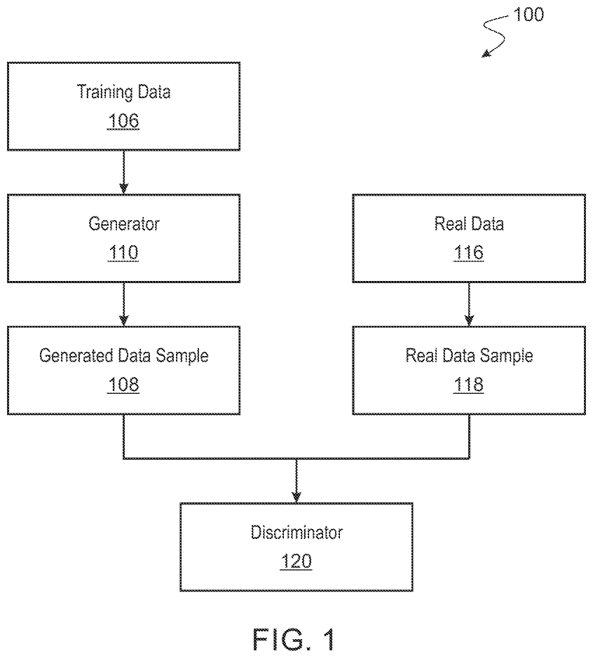

FIG. 1 shows a generative adversarial network 100 that predicts gas rates according to the present techniques.

Two neural networks are shown in FIG. 1, a generator 110 and a discriminator 120. In the GAN 100, the two neural networks compete against each other in a game-like scenario. The generator 110 is tasked with generating new data samples (e.g., generated data samples 108) that are similar to the training data 106. In examples, the generated data samples 108 are fake data samples. The discriminator 120 is tasked with distinguishing between real data samples 118 and the generated data samples 108 generated by the generator 110. The real data samples are extracted from real data 116. The generator 110 and the discriminator 120 are trained simultaneously, with the generator 110 attempting to generate increasingly realistic data samples 108 that can fool the discriminator 120, and the discriminator 120 becoming increasingly better at distinguishing between real data samples 118 and generated data samples 108.

In examples, the training data 106 is obtained from historical data. The training data is, for example, a collection of input data samples comprising labels and values. In the context of estimating gas rates, the training data includes data such as choke size, well head temperature, pressure, and other relevant factors, along with corresponding gas rate measurements. In examples, training data includes a well number, flowing wellhead pressure (FWHP), oil condensate (Million standard cubic feet per day (MMSCFD)), oil condensate (stock tank barrel (STB)), water (barrels of water per day (BWPD)), Basic Sediment and Water (BS&W), chloride, carbon dioxide (CO2), hydrogen sulfide (H2S), water gas ratio (WGR), condensate to gas ratio (CGR) (STB/MMSCFD), estimated oil condensate (STB), estimated GOR (SCF/STB), well test GOR (SCF/STB), estimated cond. banking impact, percent cond. drop out, estimated surface inflow performance relationship (IPR), UPST-1000, and (UPST-1000)/Gas.

Table 1A and Table 1B provide an example of labels and values associated with training data.

TABLE 1A

| | | Choke | | | | Oil | | | | | |
|---|---|---|---|---|---|---|---|---|---|---|---|
| Well | | Size | FWHP | WHT | Gas Rate | Conden | Water | BS&W | Chloride | CO2 | H2S |
| Number | | (/64) | (psig) | (F) | (MMSCFD) | (STB) | (BWPD) | (%) | (mg/l) | (%) | (ppm) |
| XX-297 | 99 | 24/64″ | 1550 | 160 | 15 | 2250 | 1200.907 | 40 | 13120 | 2 | 15000 |

TABLE 1B

| | | | | | Estimated | % | | | |
|---|---|---|---|---|---|---|---|---|---|
| WGR (BBls | CGR | Est Oil | Estimated | WellTest | Cond | Cond. | Estim. | | (UPST- |
| Water/ | (STB/ | Condensate | GOR | GOR | Banking | Drop | Surface | (UPST- | 1000)/ |
| MMSCFD) | MMSCFD) | (STB) | (SCF/STB) | (SCF/STB) | Impact | Out | IPR | 1000) | Gas |
| 35.569 | 76.86048 | 4490.117 | 10229.13 | 1259.13 | 0 | 0 | 7.66781 | 1250 | 69.42857 |

In examples, the real data 116 is obtained from historical data. The real data 116 includes, for example, actual, observed data at a well. In some embodiments, the label types or features in the training data 106 corresponds to the real data 116. Additionally, in some embodiments, a type or classification of the available training data 106 guides the selection of real data 116 for training. For example, if training data 106 includes values labeled as a FWHP, oil condensate (MMSCFD), oil condensate (STB), water (BWPD), the selected real data 116 includes but is not limited to FWHP, oil condensate (MMSCFD), oil condensate (STB), and water (BWPD) and water measured at a physical well.

In examples, the real data 116 is data used to estimate gas rates. Additionally, in examples the real data 116 is data that is modeled and used to make predictions. In the case of gas rate estimation, real data is, for example, actual gas rate measurements collected from a gas system or process. In examples, the real data is split into training data and testing data, and used to train and test a supervised regression model, respectively. Additionally, in examples, the real data 116 is testing data that is differentiated from the fake data generated by the model.

In examples, the generator 110 is a regression model that estimates gas rates given the input features of the training data. The generator 110 is trained using regression analysis by fitting a function to a set of data points extracted from the training data. The generator 110 determines a relationship between the input features and predicted gas rates. Accordingly, the generator 110 predicts continuous gas rates based on the value of one or more input variables. During training, when the discriminator 120 successfully identifies real and fake samples, the discriminator is rewarded, and no change is needed to the model parameters of the discriminator 120. In this case, the generator 110 is penalized with updates to model parameters of the generator 110. When the generator 110 fools the discriminator 120, the generator 110 is rewarded, and no change is needed to the model parameters of the generator 110. In this case, the discriminator 120 is penalized and the model parameters of the discriminator are updated. Once the generator 110 successfully fools the discriminator 120 and the GAN meets performance metrics based on the predicted gas rates, the trained model is used to predict gas rates on unseen data.

In examples, a GAN is used as a regression model by training it to generate gas rate values based on input features such as choke size, well head temperature, pressure, etc. The generator network (e.g., generator 110) of the GAN is trained to produce synthetic gas rate values (e.g., generated data samples 108) that mimic the distribution of the real data (e.g., real data samples 118). The discriminator network (e.g., discriminator 120) is trained to differentiate between the real gas rate values and the generated (synthetic) gas rate values (e.g., generated data samples 108). By iteratively training these networks (e.g., generator 110 and discriminator 120) together, the GAN learns to generate gas rate estimates that closely match the characteristics of the real data.

In some embodiments, GANs used for regression in gas rate estimation include an architecture as described herein. The architecture differs from the traditional GANs used for tasks like image generation. In examples, GANs according to the present techniques include changes in the architecture of the generator and discriminator networks, adjustments to the loss functions used during training to enhance the regression capabilities of the model.

In examples, multiple performance metrics are used to evaluate the model performance, including Average Absolute Percentage Error (AAPE), Mean Absolute Percentage Error (MAPE), Mean Squared Error (MSE), and Coefficient of Determination (R\hat{ }2). In examples, the AAPE is the average percentage difference between the predicted values and the actual values. An AAPE of 0.05 means that, on average, the predictions are off by 5%. The MAPE is similar to AAPE, but it takes the absolute value of the percentage difference and averages it. An MAPE of 0.05 means that, on average, the predictions are off by 5%. The MSE calculates the average of the squared differences between the predicted values and the actual values. A lower MSE means that the predictions are closer to the actual values. The R\hat{ }2 represents the proportion of variance in the target variable that is predictable from the input variables. An R\hat{ }2 of 0.99 means that 99% of the variance in the target variable is explained by the input variables. In examples, evaluating the discriminator comprises calculating at least one performance metric and determining that the at least one performance metric satisfies a corresponding performance metric threshold. For example, a lower AAPE, MAPE, and MSE and a higher R\hat{ }2 indicate better model performance. In examples, particular threshold values for satisfactory performance by the discriminator, the generator, or any combination thereof will vary depending on factors such as the domain, the significance of the problem, and the acceptable level of error or deviation. Domain knowledge, historical performance, and the specific features of the application is considered when setting threshold values. In an example, the performance of a model as described herein may be considered acceptable with an AAPE of 9.5%. However, other values can indicate satisfactory performance.

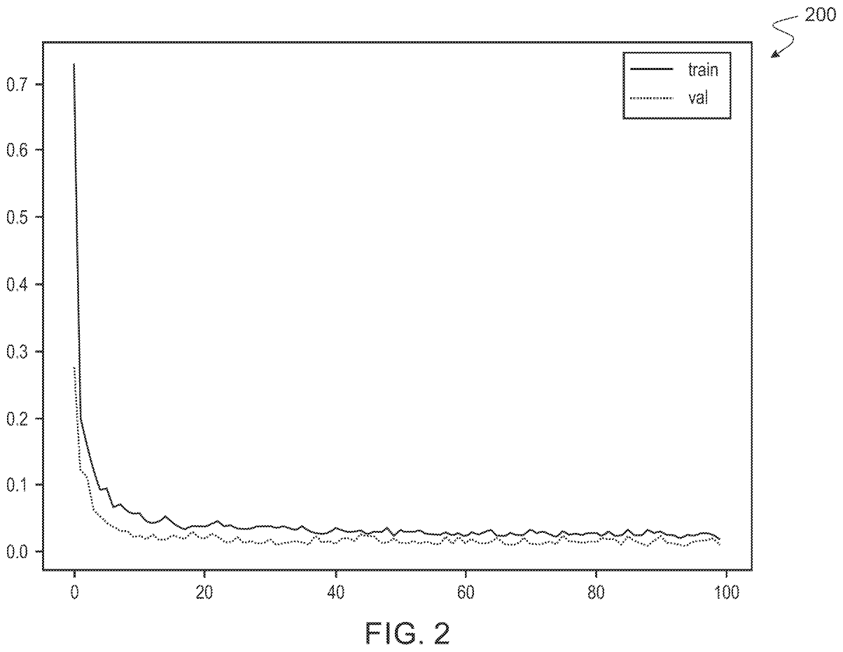

FIG. 2 is a plot of the learning curves 200 associated with the GAN. The learning curves show training and validation scores on the y-axis against varying samples of the training dataset on the x-axis. Accordingly, the learning curves 200 are plots of the GANs performance on the training set and the validation set as a function of varying samples of training dataset.

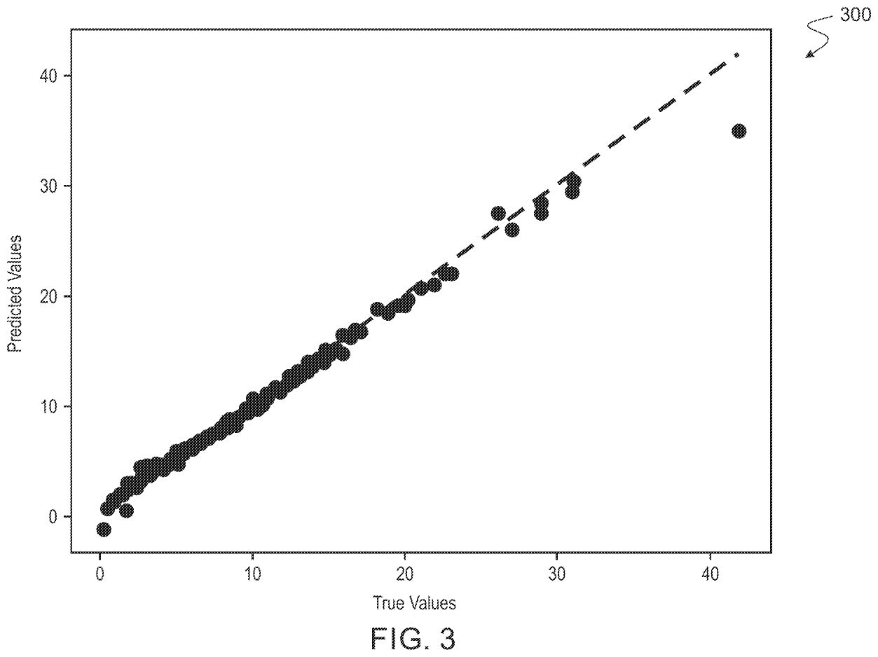

FIG. 3 is a GAN scatter plot 300. The scatter plot 300 is a data visualization that shows relationships between the predicted gas rates from the GAN and the actual gas rates. In supervised machine learning, the scatter plot 300 visualizes the predicted value versus the true value of the GAN, which enables a visual comparison of the performance of different regression models. Some common regression models include linear regression, support vector regression (SVR), decision trees, random forest, gradient boosting regression and neural networks. Linear regression models the relationship between the input features and the target variable using a linear equation. SVR uses support vector machines to perform regression tasks by finding a hyperplane that best fits the data. Decision tree-based regression models partition the input feature space into regions to make predictions. Random forest is an ensemble method that combines multiple decision trees for regression tasks. Gradient Boosting Regression: Gradient boosting algorithms like XGBoost or LightGBM iteratively build a strong regression model by combining weak learners. Neural networks, including deep learning models, can be used for regression tasks by training on input features and target variables.

The scatter plots of the predicted values versus the true values for each model provide insights into the accuracy of the predictions, the degree of correlation between the predicted and true values, and the presence of outliers or nonlinear relationships. By comparing the scatter plots of different models, models that have better predictive power are identified, and models that need improvement are identified. The scatter plot 300 also enables observation of the differences in the distribution of the predicted values and the true values, which can provide information about the bias and variance of the model. As shown in FIG. 3, the GAN accurately predicts gas rates that are close to the true gas rates. The GAN performs well, with a low error rate and high accuracy in predicting the gas rates.

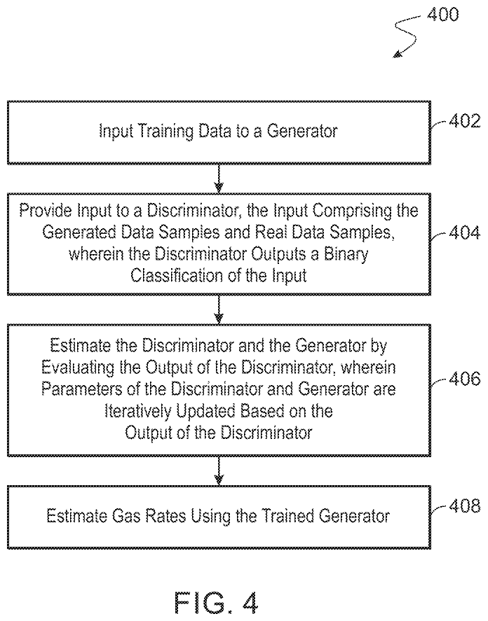

The following code describes using GANs as a regression model to predict the gas rate of a well as described with respect to FIG. 1 and FIG. 4:

```
#Import libraries
import numpy as np
import pandas as pd
import matplotlib.pyplot as plt
from sklearn.model_selection import train_test_split
from sklearn.preprocessing import MinMaxScaler
from tensorflow.keras.models import Sequential
from tensorflow.keras.layers import Dense
from tensorflow.keras.optimizers import Adam
from sklearn.metrics import mean_squared_error, r2_score, mean_absolute_error
# Load the dataset from an Excel file
try:
  df = pd.read_excel(“datauncleaned1.xlsx”)
except:
  print(“Failed to load the Excel file.”)
# Split the dataset into input and output variables
X = df.drop(‘Gas Rate (MMSCFD)’, axis=1).values
y = df[‘Gas Rate (MMSCFD)’].values
# Normalize the input and output variables
scaler_x = MinMaxScaler( )
X = scaler_x.fit_transform(X)
scaler_y = MinMaxScaler( )
y = scaler_y.fit_transform(y.reshape(−1, 1))
# Split the data into train and test sets
X_train, X_test, y_train, y_test = train_test_split(X, y, test_size=0.2,
random_state=42)
# Define the generator model
def build_generator(latent_dim, num_features):
  model = Sequential( )
  model.add(Dense(16, input_dim=latent_dim, activation=‘relu’))
  model.add(Dense(32, activation=‘relu’))
  model.add(Dense(num_features, activation=‘linear’))
  return model
# Define the discriminator model
def build_discriminator(num_features):
  model = Sequential( )
  model.add(Dense(32, input_shape=(num_features,), activation=‘relu’))
  model.add(Dense(16, activation=‘relu’))
  model.add(Dense(1, activation=‘sigmoid’))
  model.compile(loss=‘binary_crossentropy’, optimizer=‘adam’, metrics=[‘accuracy’])
  return model
# Define the GAN model
def build_gan(generator, discriminator):
discriminator.trainable = False
  model = Sequential( )
  model.add(generator)
  model.add(discriminator)
  model.compile(loss=‘binary_crossentropy’, optimizer=‘adam’)
  return model
# Define mean_absolute_percentage_error function
def mean_absolute_percentage_error(y_true, y_pred):
  y_true, y_pred = np.array(y_true), np.array(y_pred)
  return np.mean(np.abs((y_true − y_pred) / y_true)) * 100
# Define the training loop
def train(gan, generator, discriminator, X_train, latent_dim, num_epochs=100,
batch_size=128):
  # Define labels for real and fake data
  y_real = np.ones((batch_size, 1))
  y_fake = np.zeros((batch_size, 1))
  # Iterate over epochs
  for epoch in range(num_epochs):
    # Iterate over batches
    for batch_start in range(0, len(X_train)−batch_size, batch_size):
      # Generate fake data
      z = np.random.normal(0, 1, (batch_size, latent_dim))
      X_fake = generator.predict(z)
      # Select a batch of real data
      batch_end = batch_start + batch_size
      X_real = X_train[batch_start:batch_end]
      # Combine real and fake data
      X_combined = np.vstack((X_real, X_fake))
      y_combined = np.vstack((y_real, y_fake))
      # Train discriminator
      discriminator_loss = discriminator.train_on_batch(X_combined, y_combined)
      # Train generator
      z = np.random.normal(0, 1, (batch_size, latent_dim))
      generator_loss = gan.train_on_batch(z, y_real)
    # Print progress
    if epoch % 10 == 0:
      print(“Epoch:”, epoch, “Discriminator Loss:”, discriminator_loss[0],
“Generator Loss:”, generator_loss)
# Define the dimensions of the input data and the latent space
num_features = X_train.shape[1]
latent_dim = 10
# Create the generator, discriminator, and GAN models
generator = build_generator(latent_dim, num_features)
discriminator = build_discriminator(num_features)
gan = build_gan(generator, discriminator)
# Train the GAN
train(gan, generator, discriminator, X_train, latent_dim, num_epochs=100,
batch_size=128)
# Create a function for evaluation
def evaluate_generator(generator, X_test, y_test, scaler_y):
  # Generate synthetic gas rate samples
  z = np.random.normal(0, 1, (len(X_test), latent_dim))
  X_fake = generator.predict(z)
  y_fake = scaler_y.inverse_transform(X_fake)
  y_fake = np.mean(y_fake, axis=1)
    # Inverse transform the real validation data
  X_test_orig = scaler_x.inverse_transform(X_test)
  y_test_orig = scaler_y.inverse_transform(y_test)
  y_test_orig = np.mean(y_test_orig, axis=1)
  # Calculate evaluation metrics
  mse_fake = mean_squared_error(y_test_orig, y_fake)
  r2_fake = r2_score(y_test_orig, y_fake)
  mae_fake = mean_absolute_error(y_test_orig, y_fake)
  mape_fake = mean_absolute_percentage_error(y_test_orig, y_fake)
  return mse_fake, r2_fake, mae_fake, mape_fake
# Evaluate the GAN on the test data
mse_fake, r2_fake, mae_fake, mape_fake = evaluate_generator(generator, X_test,
y_test, scaler_y)
# Print the results
print(“MSE (fake):”, mse_fake)
print(“R2 score (fake):”, r2_fake)
print(“MAE (fake):”, mae_fake)
print(“MAPE (fake):”, mape_fake)
```

As shown in the code above, estimating a gas rate using GANs includes data preparation. In data preparation, data is collected, cleaned and normalized. In examples, historical data related to gas rate and relevant features (e.g., temperature, pressure) is collected. The data is preprocessed, including cleaning, normalization, and splitting into training and testing sets. In examples, preprocessing includes scaling the data. Scaling the data standardizes features by subtracting the mean and dividing by the standard deviation. This transforms the data to have a mean of 0 and a standard deviation of 1. Other scaling techniques may also be used depending on the specific requirements and characteristics of the data. Scaling the data ensures fair representation of features, improves convergence, enhances interpretability, handles outliers, and promotes model compatibility.

The generator model is defined according to an architecture and activation functions. In examples, the generator model is a generator neural network that takes random noise as input and generates synthetic gas rate samples as output. The generator architecture includes a number of layers and neurons per layer. In examples, the generator is a sequential model configured to include 16 neurons in a first hidden layer and input parameters set according to a latent dimension variable. In examples, the generator is a sequential model configured to include 32 neurons in a second hidden layer. In examples, the activation function is a rectified linear unit (relu).

The discriminator model is defined according to an architecture and activation functions. In examples, the discriminator model is a discriminator neural network neural network that classifies whether a given gas rate sample is real (from the dataset) or fake (generated by the generator). The discriminator architecture includes a number of layers and neurons per layer. In examples, the discriminator is a sequential model configured to include 32 neurons in a first hidden layer and input parameter shape set according to a number of features. In examples, the discriminator is a sequential model configured to include 16 neurons in a second hidden layer with a rectified linear unit activation function. In examples, the discriminator is a sequential model configured to include one neuron in a third layer with a sigmoid activation function.

In examples, the discriminator is compiled including the loss functions and optimizer, then the GAN is compiled including the loss functions and optimizers. Compiling the GAN model combines the generator and discriminator. In examples, the discriminator is compiled with an appropriate loss function and optimizer, and the discriminator to be non-trainable during GAN training.

In examples, train the GAN includes generating fake samples, combining real and fake data, and training the discriminator and generator. To train the GAN, the number of epochs and batch size is set for training. Training steps are performed iteratively during each epoch. In each epoch, fake gas rate samples are generated by the generator using random noise as input, real and fake samples are combined, the discriminator is trained to distinguish between real and fake samples, and the generator is trained to generate more realistic gas rate samples. Training is performed iteratively for the specified number of epochs.

Gas rate predictions are generated using a trained generator for new or unseen data. In some embodiments, the scaled predictions back to the original scale, if necessary. Inverse transform predictions are determined using reverse scaling. In some embodiments, the model is evaluated using the gas rate predictions. For example, the evaluation metrics (e.g., AAPE, MAPE, MSE, R\hat{ }2) are calculated to assess the performance of the GAN-based gas rate estimation.

After evaluation, the GAN is adjusted using fine tuning and optimization. In examples, the GAN model and hyperparameters are fine-tuned based on the evaluation results. In examples, training and evaluation is iteratively performed to improve model performance. In some embodiments, the GAN is deployed and monitored during use in real-time gas rate estimation. Once satisfied with the GAN's performance, the GAN is deployed for real-time gas rate estimation. Performance of the GAN is continuously monitored and the GAN is updated as new data becomes available or as needed.

The development of AI models for flowback operations enables efficient and accurate estimation of gas rates. The use of an estimated gas rate enables engineers would be able to increase the speed and accuracy of post-drilling evaluation and ongoing production optimization. Ultimately, this results in a reduction in operating costs, as well as an increase in returns on investment. Furthermore, the application of AI models to the exploration process provides further savings, as the accurate prediction of gas rate enables engineers to make more informed decisions regarding the exploration and production of new wells. Thus, the present techniques provide cost-savings, increased efficiency, and improved returns.

FIG. 4 is a process flow diagram of a method for predicting gas rates using a generative adversarial network.

At block 402, a generator obtains training data and outputs generated data samples. In examples, prior to outputting the generated data samples, the data preparation is performed.

At block 404, a discriminator obtains input comprising the generated data samples and real data samples, and outputs a binary classification of the inputs. In examples, the discriminator classifies the input as real or fake.

At block 406, the discriminator and the generator are trained by evaluating the output of the discriminator, wherein parameters of the discriminator and generator are iteratively updated based on the output of the discriminator.

At block 408, gas rates are estimated by the trained generator. In examples, unseen data is input to the trained generator, and gas rates are estimated. In this manner, the trained generator yields efficient estimation of gas rate, and engineers are able to increase the speed and accuracy of post-drilling evaluation and ongoing production optimization. This could lead to a reduction in operating costs, as well as an increase in returns on investment. The present techniques provide a better estimation of gas rate when compared to choke equations and less costly than utilizing a mobile or fixed gas separator. In examples, the estimated gas rates are used to determine locations for new wells. For example, a low estimated gas rate discourages further drilling of new wells located near the well corresponding to the estimated gas rate. In another example, a high estimated gas rate encourages further drilling of new wells located near the well corresponding to the estimated gas rate.

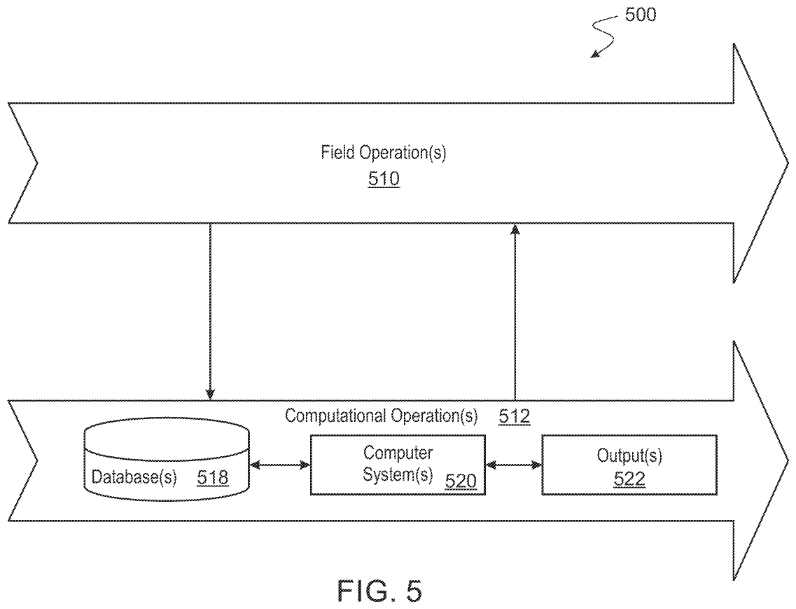

FIG. 5 illustrates hydrocarbon production operations 500 that include both one or more field operations 510 and one or more computational operations 512, which exchange information and control exploration for the production of hydrocarbons. In some implementations, outputs of techniques of the present disclosure can be performed before, during, or in combination with the hydrocarbon production operations 500, specifically, for example, either as field operations 510 or computational operations 512, or both.

Examples of field operations 510 include forming/drilling a wellbore, hydraulic fracturing, producing through the wellbore, injecting fluids (such as water) through the wellbore, to name a few. In some implementations, methods of the present disclosure can trigger or control the field operations 510. For example, the methods of the present disclosure can generate data from hardware/software including sensors and physical data gathering equipment (e.g., seismic sensors, well logging tools, flow meters, and temperature and pressure sensors). The methods of the present disclosure can include transmitting the data from the hardware/software to the field operations 510 and responsively triggering the field operations 510 including, for example, generating plans and signals that provide feedback to and control physical components of the field operations 510. Alternatively or in addition, the field operations 510 can trigger the methods of the present disclosure. For example, implementing physical components (including, for example, hardware, such as sensors) deployed in the field operations 510 can generate plans and signals that can be provided as input or feedback (or both) to the methods of the present disclosure.

Examples of computational operations 512 include one or more computer systems 520 that include one or more processors and computer-readable media (e.g., non-transitory computer-readable media) operatively coupled to the one or more processors to execute computer operations to perform the methods of the present disclosure. The computational operations 512 can be implemented using one or more databases 518, which store data received from the field operations 510 and/or generated internally within the computational operations 512 (e.g., by implementing the methods of the present disclosure) or both. For example, the one or more computer systems 520 process inputs from the field operations 510 to assess conditions in the physical world, the outputs of which are stored in the databases 518. For example, seismic sensors of the field operations 510 can be used to perform a seismic survey to map subterranean features, such as facies and faults. In performing a seismic survey, seismic sources (e.g., seismic vibrators or explosions) generate seismic waves that propagate in the earth and seismic receivers (e.g., geophones) measure reflections generated as the seismic waves interact with boundaries between layers of a subsurface formation. The source and received signals are provided to the computational operations 512 where they are stored in the databases 518 and analyzed by the one or more computer systems 520.

In some implementations, one or more outputs 522 generated by the one or more computer systems 520 can be provided as feedback/input to the field operations 510 (either as direct input or stored in the databases 518). The field operations 510 can use the feedback/input to control physical components used to perform the field operations 510 in the real world.

For example, the computational operations 512 can process the seismic data to generate three-dimensional (3D) maps of the subsurface formation. The computational operations 512 can use these 3D maps to provide plans for locating and drilling exploratory wells. In some operations, the exploratory wells are drilled using logging-while-drilling (LWD) techniques which incorporate logging tools into the drill string. LWD techniques can enable the computational operations 512 to process new information about the formation and control the drilling to adjust to the observed conditions in real-time.

The one or more computer systems 520 can update the 3D maps of the subsurface formation as information from one exploration well is received and the computational operations 512 can adjust the location of the next exploration well based on the updated 3D maps. Similarly, the data received from production operations can be used by the computational operations 512 to control components of the production operations. For example, production well and pipeline data can be analyzed to predict slugging in pipelines leading to a refinery and the computational operations 512 can control machine operated valves upstream of the refinery to reduce the likelihood of plant disruptions that run the risk of taking the plant offline.

In some implementations of the computational operations 512, customized user interfaces can present intermediate or final results of the above-described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or app), or at a central processing facility.

The presented information can include feedback, such as changes in parameters or processing inputs, that the user can select to improve a production environment, such as in the exploration, production, and/or testing of petrochemical processes or facilities. For example, the feedback can include parameters that, when selected by the user, can cause a change to, or an improvement in, drilling parameters (including drill bit speed and direction) or overall production of a gas or oil well. The feedback, when implemented by the user, can improve the speed and accuracy of calculations, streamline processes, improve models, and solve problems related to efficiency, performance, safety, reliability, costs, downtime, and the need for human interaction.

In some implementations, the feedback can be implemented in real-time, such as to provide an immediate or near-immediate change in operations or in a model. The term real-time (or similar terms as understood by one of ordinary skill in the art) means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second (s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

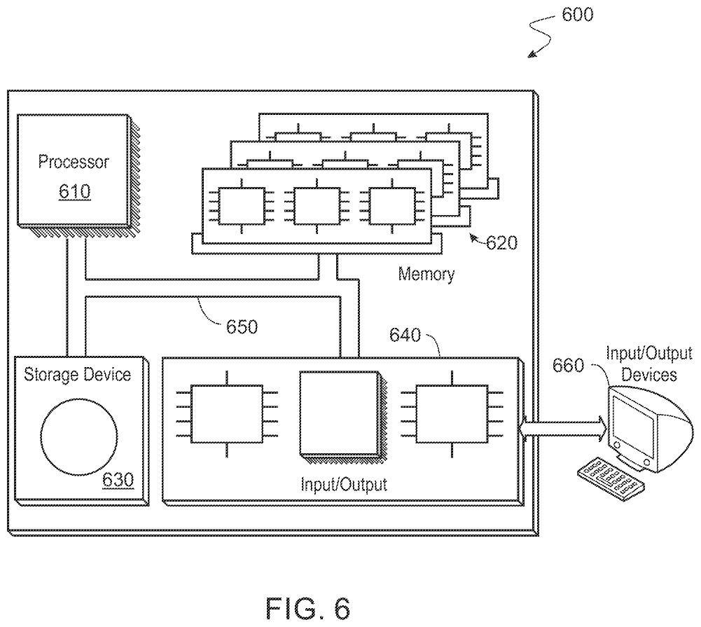

FIG. 6 is a schematic illustration of an example controller 600 (or control system) for estimating gas rate using a generative adversarial network. For example, the controller 600 may be operable according to the workflow 200 of FIG. 2 or the process 1110 of FIG. 11. The controller 600 is intended to include various forms of digital computers, such as printed circuit boards (PCB), processors, digital circuitry, or otherwise parts of a system for supply chain alert management. Additionally the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 600 includes a processor 610, a memory 620, a storage device 630, and an input/output interface 640 communicatively coupled with input/output devices 660 (for example, displays, keyboards, measurement devices, sensors, valves, pumps). Each of the components 610, 620, 630, and 640 are interconnected using a system bus 650. The processor 610 is capable of processing instructions for execution within the controller 600. The processor may be designed using any of a number of architectures. For example, the processor 610 may be a CISC (Complex Instruction Set Computers) processor, a RISC (Reduced Instruction Set Computer) processor, or a MISC (Minimal Instruction Set Computer) processor.

In one implementation, the processor 610 is a single-threaded processor. In another implementation, the processor 610 is a multi-threaded processor. The processor 610 is capable of processing instructions stored in the memory 620 or on the storage device 630 to display graphical information for a user interface on the input/output interface 640.

The memory 620 stores information within the controller 600. In one implementation, the memory 620 is a computer-readable medium. In one implementation, the memory 620 is a volatile memory unit. In another implementation, the memory 620 is a nonvolatile memory unit.

The storage device 630 is capable of providing mass storage for the controller 600. In one implementation, the storage device 630 is a computer-readable medium. In various different implementations, the storage device 630 may be a floppy disk device, a hard disk device, an optical disk device, or a tape device.

The input/output interface 640 provides input/output operations for the controller 600. In one implementation, the input/output devices 660 includes a keyboard and/or pointing device. In another implementation, the input/output devices 660 includes a display unit for displaying graphical user interfaces.

There can be any number of controllers 600 associated with, or external to, a computer system containing controller 600, with each controller 600 communicating over a network. Further, the terms “client,” “user,” and other appropriate terminology can be used interchangeably, as appropriate, without departing from the scope of the present disclosure. Moreover, the present disclosure contemplates that many users can use one controller 600 and one user can use multiple controllers 600.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatus, devices, and machines for processing data, including by way of example, a programmable processor, a computer, or multiple processors or computers. The apparatus can also include special purpose logic circuitry including, for example, a central processing unit (CPU), a field programmable gate array (FPGA), or an application specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, for example, LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory. A computer can also include, or be operatively coupled to, one or more mass storage devices for storing data. In some implementations, a computer can receive data from, and transfer data to, the mass storage devices including, for example, magnetic, magneto optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random access memory (RAM), read only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/−R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that is used by the user. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship. Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

Particular embodiments of the subject matter have been described. Other embodiments are within the scope of the following claims. For example, the actions recited in the claims can be performed in a different order and still achieve desirable results. As one example, some processes depicted in the accompanying figures do not necessarily require the particular order shown, or sequential order, to achieve desirable results.

What is claimed is:

1. A computer-implemented method for predicting gas rate using a Generative Adversarial Network, the method comprising:
inputting, using at least one hardware processor, training data into a generator, wherein the generator outputs generated data samples;
providing, using the at least one hardware processor, input to a discriminator, the input comprising the generated data samples and real data samples, wherein the discriminator outputs a binary classification of the input;
training, using the at least one hardware processor, the discriminator and the generator by evaluating the output of the discriminator, wherein parameters of the discriminator and generator are iteratively updated based on the output of the discriminator; and
estimating, using the at least one hardware processor, gas rates using the trained generator.

2. The computer implemented method of claim 1, wherein the binary classification classifies the inputs of the discriminator as real data or fake data.

3. The computer implemented method of claim 1, wherein the training data is historical data obtained from previously drilled wells.

4. The computer implemented method of claim 1, wherein the real data is historical data obtained from previously drilled wells.

5. The computer implemented method of claim 1, wherein evaluating the discriminator comprises calculating at least one performance metric and determining that the at least one performance metric satisfies a corresponding performance metric threshold.

6. The computer implemented method of claim 1, wherein the generator is trained using regression analysis.

7. The computer implemented method of claim 1, wherein the estimated gas rates are used to determine locations for new wells.

8. An apparatus comprising a non-transitory, computer readable, storage medium that stores instructions that, when executed by at least one processor, cause the at least one processor to perform operations comprising:
inputting training data to a generator, wherein the generator outputs generated data samples;
providing input to a discriminator, the input comprising the generated data samples and real data samples, wherein the discriminator outputs a binary classification of the input;
training the discriminator and the generator by evaluating the output of the discriminator, wherein parameters of the discriminator and generator are iteratively updated based on the output of the discriminator; and
estimating gas rates using the trained generator.

9. The apparatus of claim 8, wherein the binary classification classifies the inputs of the discriminator as real data or fake data.

10. The apparatus of claim 8, wherein the training data is historical data obtained from previously drilled wells.

11. The apparatus of claim 8, wherein the real data is historical data obtained from previously drilled wells.

12. The apparatus of claim 8, wherein evaluating the discriminator comprises calculating at least one performance metric and determining that the at least one performance metric satisfies a corresponding performance metric threshold.

13. The apparatus of claim 8, wherein the generator is trained using regression analysis.

14. The apparatus of claim 8, wherein the estimated gas rates are used to determine locations for new wells.

15. A system, comprising:
one or more memory modules;
one or more hardware processors communicably coupled to the one or more memory modules, the one or more hardware processors configured to execute instructions stored on the one or more memory models to perform operations comprising:
inputting training data to a generator, wherein the generator outputs generated data samples;
providing input to a discriminator, the input comprising the generated data samples and real data samples, wherein the discriminator outputs a binary classification of the input;
training the discriminator and the generator by evaluating the output of the discriminator, wherein parameters of the discriminator and generator are iteratively updated based on the output of the discriminator; and
estimating gas rates using the trained generator.

16. The system of claim 15, wherein the binary classification classifies the inputs of the discriminator as real data or fake data.

17. The system of claim 15, wherein the training data is historical data obtained from previously drilled wells.

18. The system of claim 15, wherein the real data is historical data obtained from previously drilled wells.

19. The system of claim 15, wherein evaluating the discriminator comprises calculating at least one performance metric and determining that the at least one performance metric satisfies a corresponding performance metric threshold.

20. The system of claim 15, wherein the generator is trained using regression analysis.
